(19) United States
(12) Patent Application Publication
(10) Pub. No.: US 2013/0050166 A1
(43) Pub. Date: Feb. 28, 2013

(54) SILICIDE GAP THIN FILM TRANSISTOR

(71) Applicants: John Hyunchul HONG, San Clemente, CA (US); Chong Uk LEE, San Diego, CA (US)

(72) Inventors: John Hyunchul HONG, San Clemente, CA (US); Chong Uk LEE, San Diego, CA (US)

(73) Assignee: QUALCOMM MEMS TECHNOLOGIES, INC., San Diego, CA (US)

(21) Appl. No.: 13/217,177

(22) Filed: Aug. 24, 2011

(51) Int. Cl. G06F 3/038; H01L 29/786; H01L 21/336

(52) U.S. Cl. 345/211; 438/158; 257/51; 257/E21.414; 257/E29.291

(57) ABSTRACT

This disclosure provides systems, methods and apparatus for fabricating thin film transistor devices. In one aspect, a substrate including a silicon layer on the substrate surface is provided. A metal layer is formed on the silicon layer. A first dielectric layer is formed on the metal layer and exposed regions of the substrate surface. The metal layer and the silicon layer are treated, and the metal layer reacts with the silicon layer to form a silicide layer and a gap between the silicide layer and the dielectric layer. An amorphous silicon layer is formed on the first dielectric layer. The amorphous silicon layer is heated and cooled. The amorphous silicon layer overlying the substrate surface cools at a faster rate than the amorphous silicon layer overlying the gap.

### TECHNICAL FIELD

This disclosure relates generally to thin film transistor devices and more particularly to fabrication methods for thin film transistor devices.

### DESCRIPTION OF THE RELATED TECHNOLOGY

Electromechanical systems (EMS) include devices having electrical and mechanical elements, actuators, transducers, sensors, optical components (including mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Hardware and data processing apparatus may be associated with electromechanical systems. Such hardware and data processing apparatus may include a thin film transistor (TFT) device. A TFT device includes a source region, a drain region, and a channel region in a semiconductor material.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of fabricating a thin film transistor (TFT) device. A substrate having a surface may include a first silicon layer on a region of the substrate surface, with the first silicon layer leaving regions of the substrate surface exposed. A first metal layer may be formed on the first silicon layer. A first dielectric layer may be formed on the first metal layer and the exposed regions of the substrate surface. The first metal layer and the first silicon layer may be treated, reacting the first metal layer with the first silicon layer to form a first silicide layer and a first gap between the first silicide layer and the first dielectric layer. An amorphous silicon layer may be formed on the first dielectric layer, with the amorphous silicon layer including a first silicon region and a second silicon region overlying the exposed regions of the substrate surface and a third silicon region overlying the first gap, with the third silicon region being between the first silicon region and the second silicon region. The amorphous silicon layer may be heated and cooled. The first silicon region and the second silicon region may cool at a faster rate than the third silicon region.

In some implementations, the first metal layer includes titanium, nickel, molybdenum, tantalum, tungsten, platinum, or cobalt. In some implementations, the third silicon region may include a single silicon grain or silicon grains, and the first and second silicon regions may include amorphous silicon or silicon grains smaller than the single silicon grain or the silicon grains in the third silicon region. In some implementations, the first gap between the first silicide layer and the first dielectric layer may be a vacuum gap.

Another innovative aspect of the subject matter described in this disclosure also can be implemented in a method of fabricating a thin film transistor (TFT) device. A substrate having a surface may include a silicon layer on a region of the surface of the substrate, with the silicon layer leaving regions of the substrate surface exposed. A metal layer may be formed on the silicon layer. A portion of the metal layer and the silicon layer may be removed to expose a portion of the substrate surface. A dielectric layer may be formed on the metal layer, the exposed regions of the substrate surface, and the exposed portion of the substrate surface. The metal layer and the silicon layer may be treated, reacting the metal layer with the silicon layer to form a silicide layer and a gap between the silicide layer and the dielectric layer. An amorphous silicon layer may be formed on the dielectric layer, the amorphous silicon layer including a first silicon region and a second silicon region overlying the exposed regions of the substrate surface and a third silicon region overlying the gap, with the third silicon region being between the first silicon region and the second silicon region. The amorphous silicon layer may be heated and cooled. The first silicon region and the second silicon region may cool at a faster rate than the third silicon region.

In some implementations, the metal layer includes titanium, nickel, molybdenum, tantalum, tungsten, platinum, or cobalt. In some implementations, the third silicon region may include a single silicon grain or silicon grains, and the first and second silicon regions may include amorphous silicon or silicon grains smaller than the single silicon grain or the silicon grains in the third silicon region.

Another innovative aspect of the subject matter described in this disclosure also can be implemented in an apparatus. The apparatus may include a substrate having a surface with a first silicide layer associated with the substrate surface. At least a portion of a first dielectric layer may be on the substrate surface. A first vacuum gap may be between the first silicide layer and the first dielectric layer. A silicon layer may be on the first dielectric layer, with the silicon layer including a first silicon region, a second silicon region, and a third silicon region. The third silicon region may overlie the first vacuum gap and may be between the first silicon region and the second silicon region. The third silicon region may include a single silicon grain or silicon grains, and the first and second silicon regions may include amorphous silicon or silicon grains smaller than the single silicon grain or the silicon grains in the third silicon region.

In some implementations, the first silicide layer may be titanium silicide, nickel silicide, molybdenum silicide, tantalum silicide, tungsten silicide, platinum silicide, or cobalt silicide. In some implementations, a thickness of the first vacuum gap may be configured to increase or decrease due to a change in atmospheric pressure. In some implementations, the apparatus may be configured to generate an absolute pressure reading. In some implementations, the absolute pressure reading may be generated by applying a fixed potential to the first silicide layer and determining a current flow between the first and second silicon regions.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A and 9B show an example of a flow diagram illustrating a manufacturing process for a thin film transistor device.

FIGS. 10A-10E show examples of schematic illustrations of various stages in a method of fabricating a thin film transistor device.

FIGS. 11A and 11B show an example of a flow diagram illustrating a manufacturing process for a thin film transistor device.

FIG. 12 shows an example of a cross-sectional schematic illustration of a partially fabricated thin film transistor device.

FIG. 13 shows an example of a flow diagram illustrating a manufacturing process for a thin film transistor device.

FIG. 14 shows an example of a cross-sectional schematic illustration of a partially fabricated thin film transistor device.

FIG. 15 shows an example of a flow diagram illustrating a manufacturing process for a thin film transistor device.

FIGS. 16A and 16B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to thin film transistor (TFT) devices and methods of their fabrication. In some implementations, a layer of a metal that forms a silicide is deposited on a layer of silicon on a substrate. For example, metals that form silicides include titanium (Ti), nickel (Ni), molybdenum (Mo), tantalum (Ta), tungsten (W), platinum (Pt), and cobalt (Co). A dielectric layer is deposited on the metal layer and the substrate, such that the metal layer and the silicon layer are encapsulated between the substrate and the dielectric layer. When the metal layer and the silicon layer are treated, the metal layer reacts with the silicon layer to form a silicide layer. During the treatment, the portion of the metal layer that is consumed by the formation of the silicide layer forms a vacuum gap between the silicide layer and the dielectric layer. The vacuum gap may form part of a gate insulator of a TFT device. Further, the vacuum gap may be useful in the fabrication of further structures that are part of a TFT device.

For example, in some implementations described herein to fabricate a TFT device, a substrate can be provided. A silicon layer can overlie a region of the substrate surface, leaving one or more other regions of the substrate surface exposed. A metal layer can be formed on the silicon layer. A first dielectric layer can be formed on the metal layer and the exposed regions of the substrate surface. The metal layer and the silicon layer can be treated, such that the metal layer reacts with the silicon layer to form a silicide layer and a gap between the silicide layer and the first dielectric layer. An amorphous silicon (a-Si) layer then can be formed on the first dielectric layer. The amorphous silicon layer can include a first silicon region and a second silicon region overlying the exposed regions of the substrate and a third silicon region overlying the gap. The third silicon region is between the first silicon region and the second silicon region. The amorphous silicon layer can then be heated and cooled. In some implementations, the first silicon region and/or the second silicon region cool at a faster rate than the third silicon region.

In some implementations, the first silicon and second silicon regions can form source and drain regions of the TFT device, the third silicon region can form a channel region of the TFT device, the silicide layer can form a gate of the TFT device, and the gap and the first dielectric layer can form a gate insulator of the TFT device. Further operations may be performed to complete the fabrication of the TFT device.

Particular implementations of the subject matter described in this disclosure can be implemented to realize one or more of the following potential advantages. Implementations may be used to fabricate a TFT device incorporating silicon with an air or a vacuum gate insulator, which can improve the performance of the TFT device. Such TFT devices may have improved field-effect mobility, making them useful for display device technologies. Further, the air or vacuum gate insulators in such TFT devices may be free of contaminants or residues that could cause device variations. Implementations of the methods also may be used to fabricate top gate TFT devices. A top gate in a TFT device may improve the gate leakage and the gate breakdown properties of the TFT device.

Further, implementations may be used as an absolute pressure sensor. With a pressure sensitive gate insulator, the absolute pressure may be related to a current flowing through the TFT device. Determining the absolute pressure in this manner may be done without complex circuitry.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

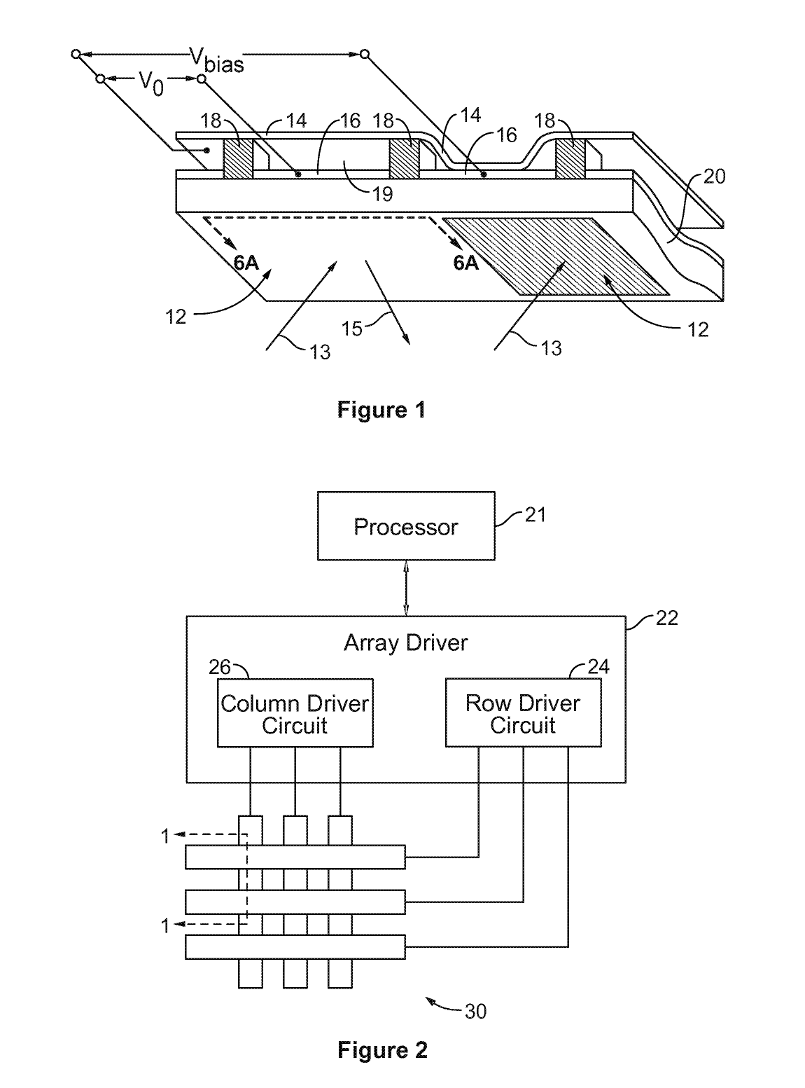

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

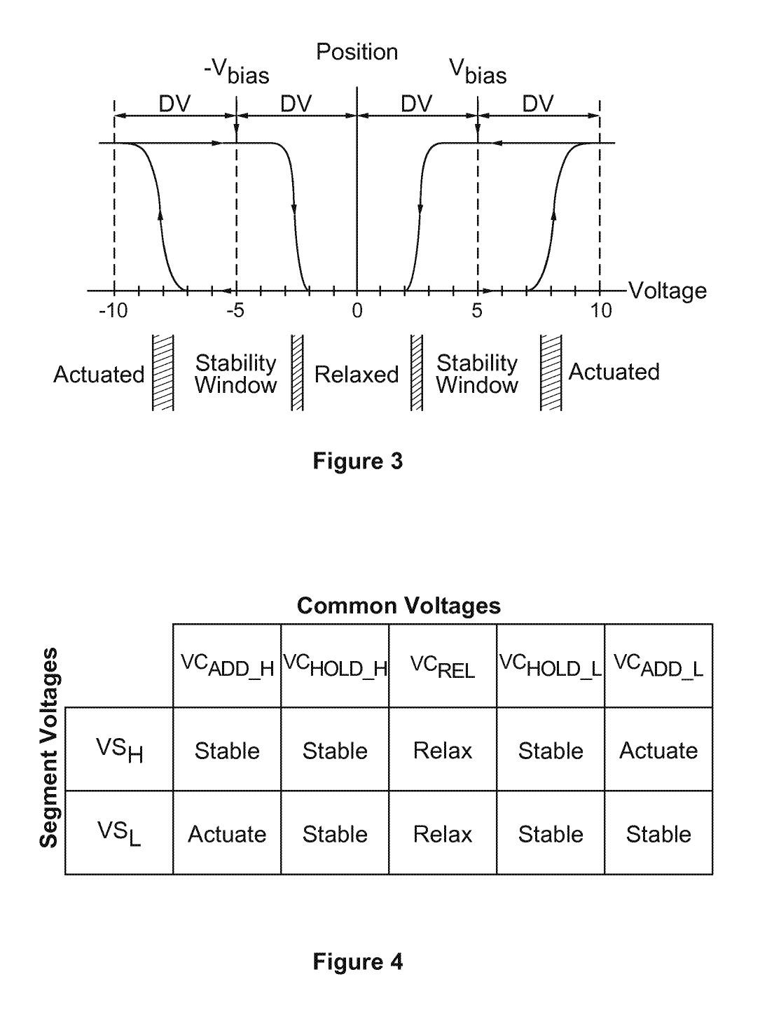

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

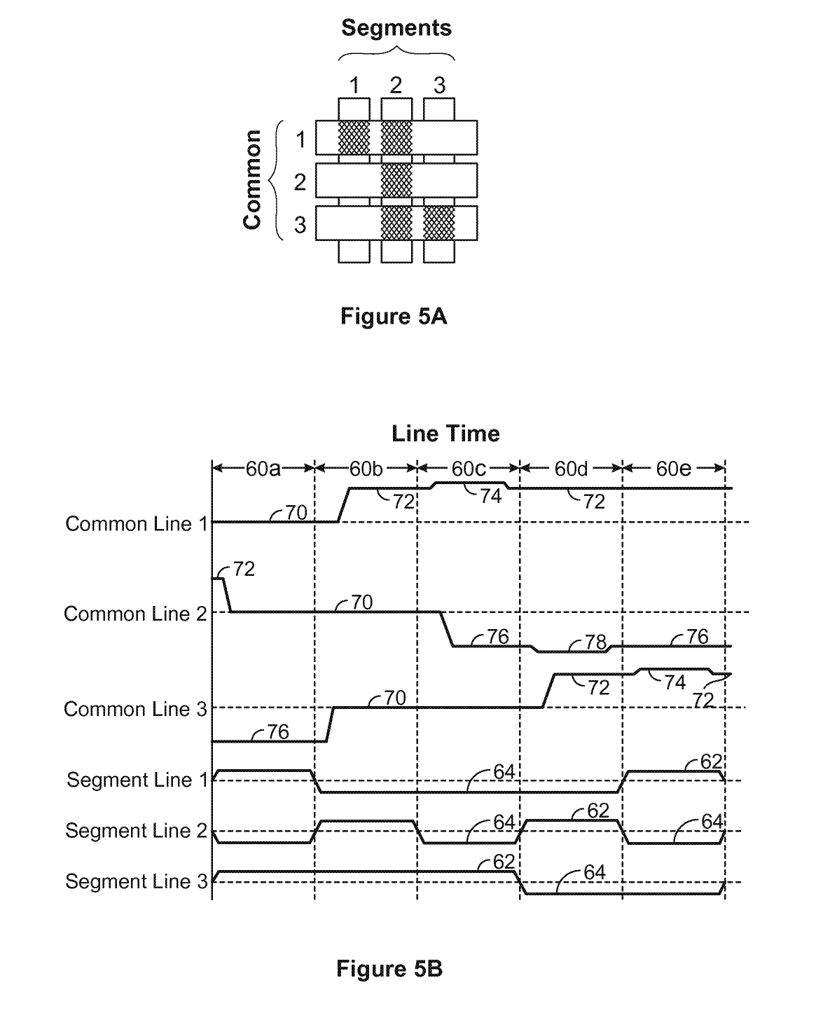

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3'33 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

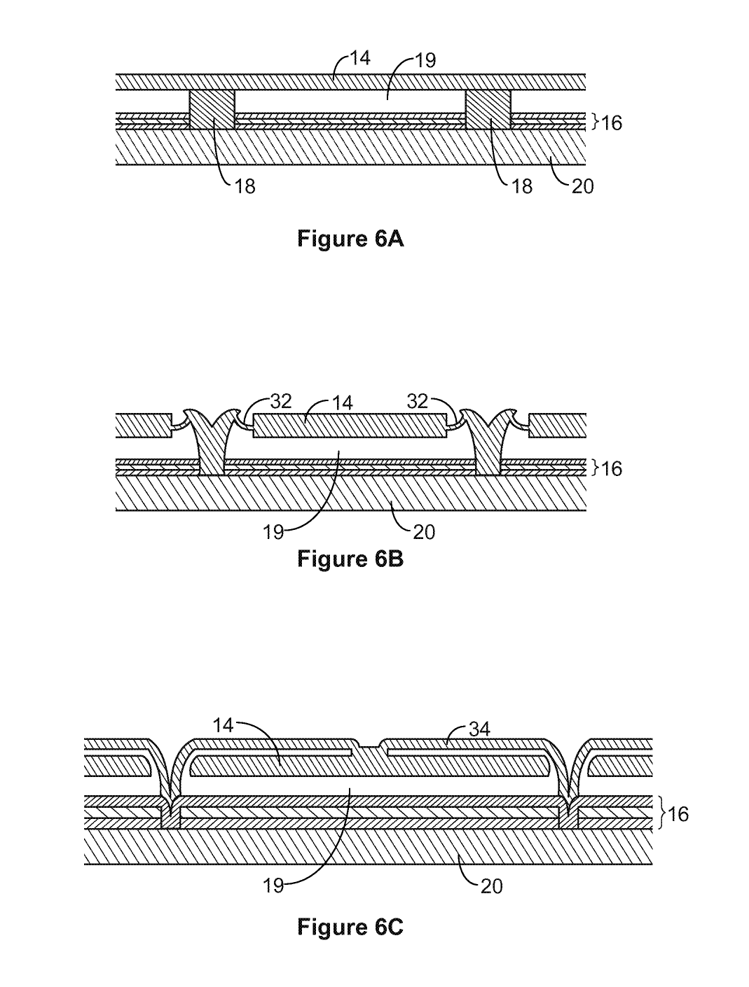

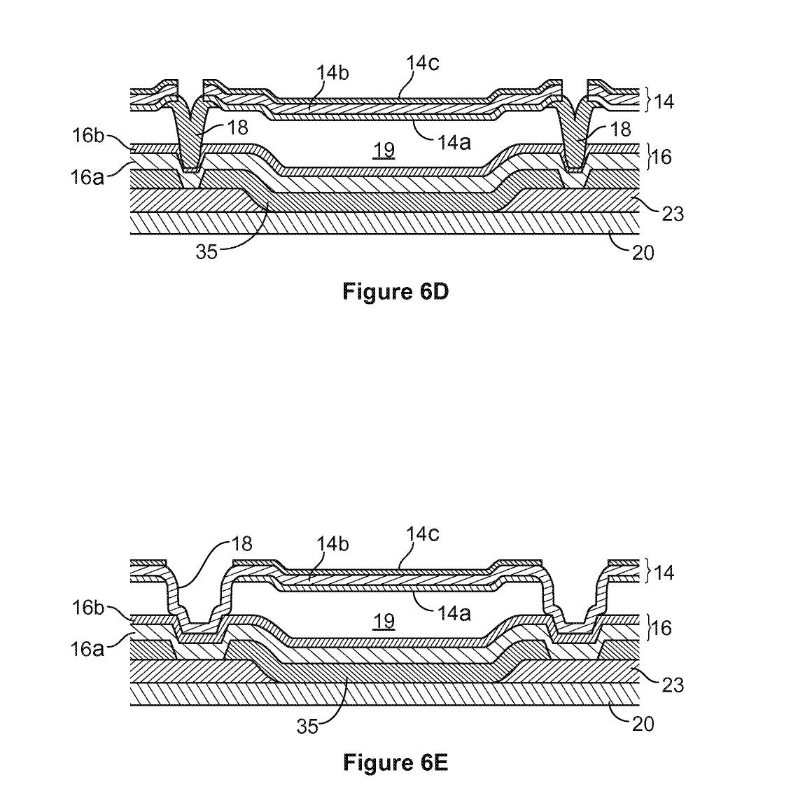

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, an SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

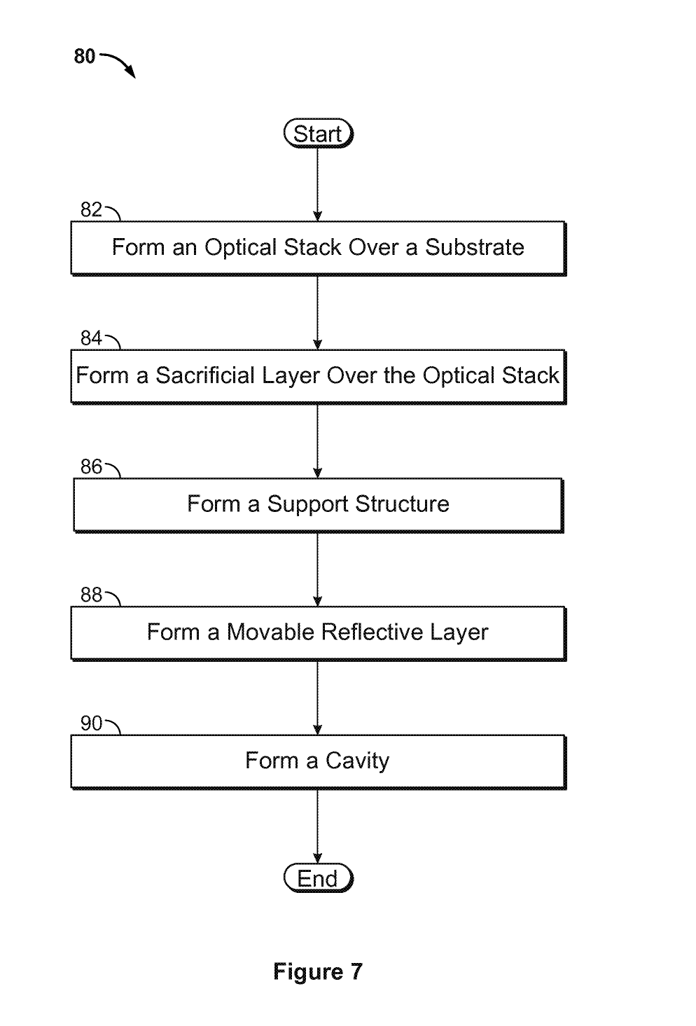

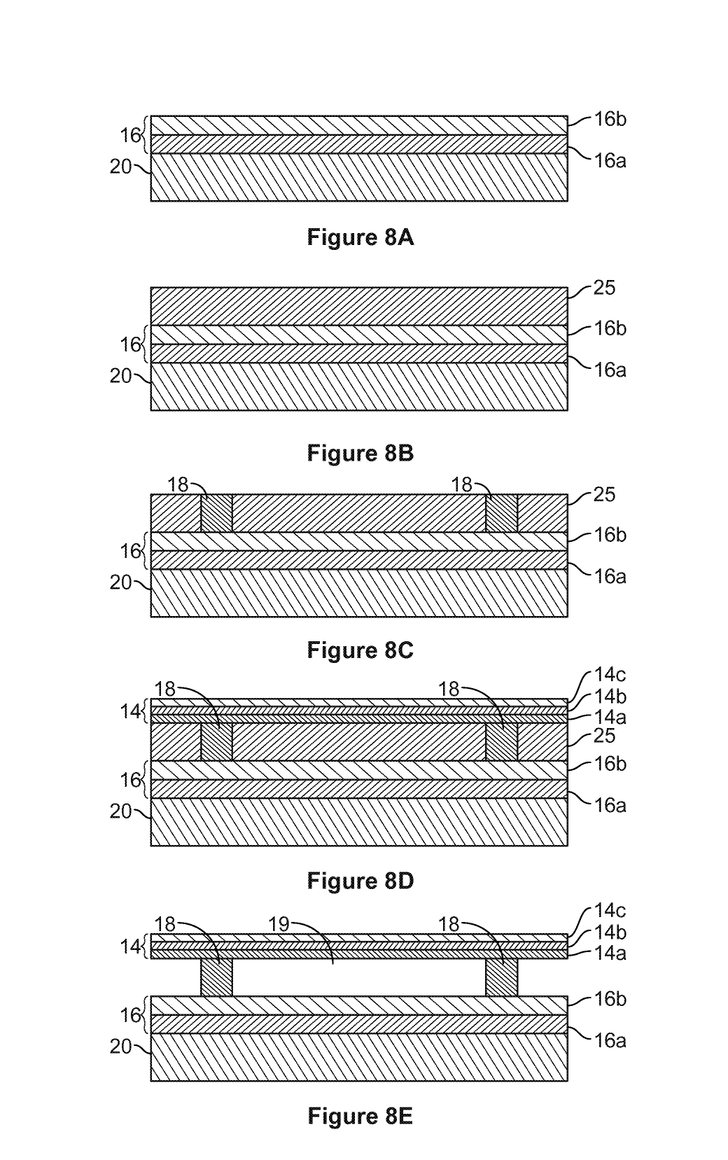

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As noted throughout, hardware and data processing apparatus may be associated with electromechanical systems, including IMOD devices. Such hardware and data processing apparatus may include a thin film transistor (TFT) device or devices.

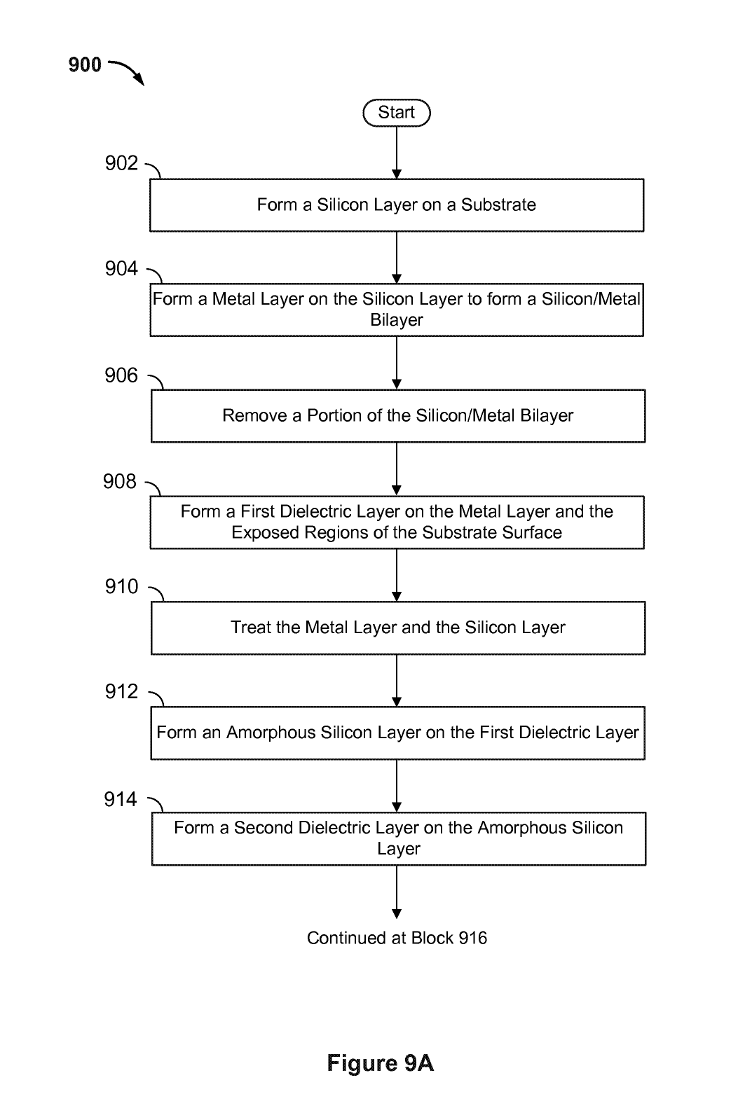

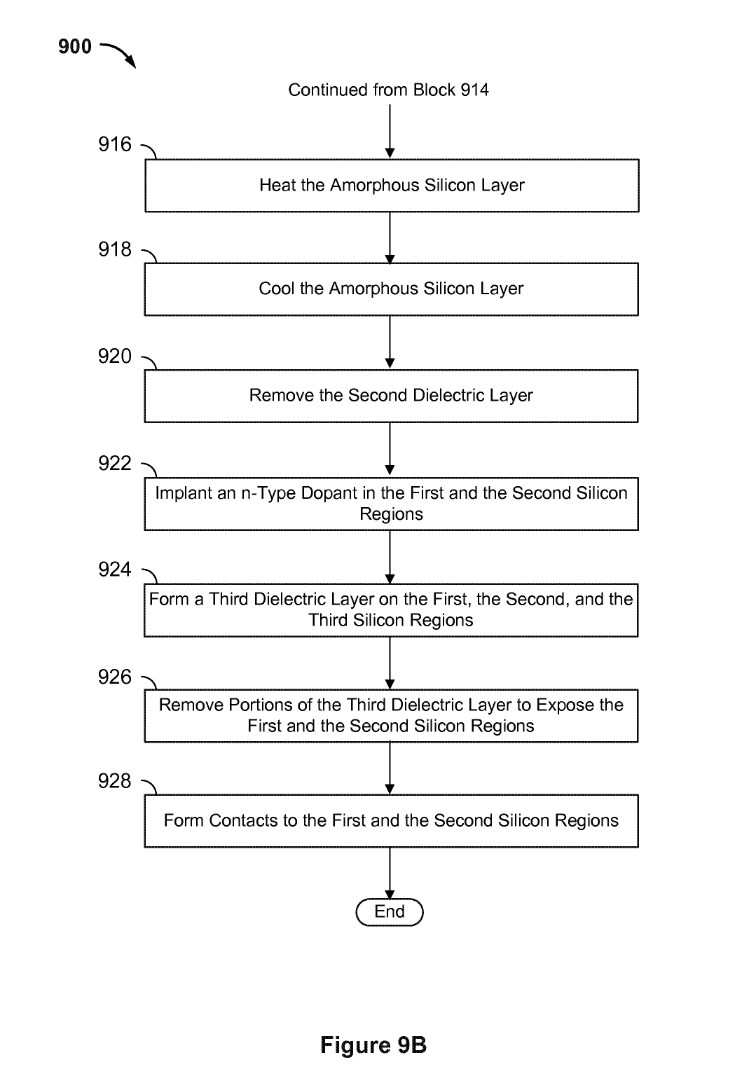

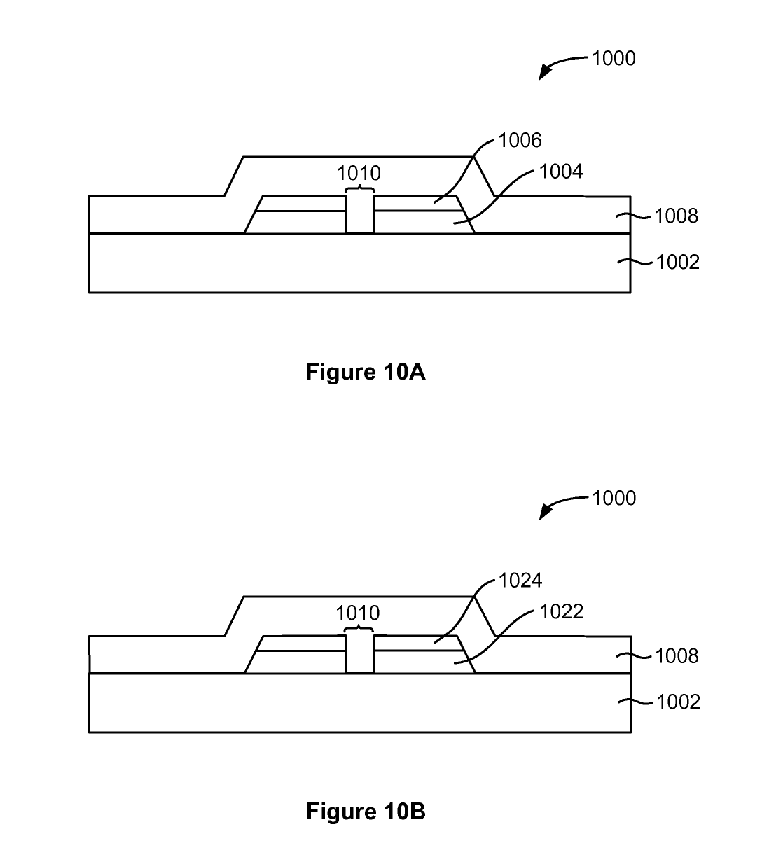

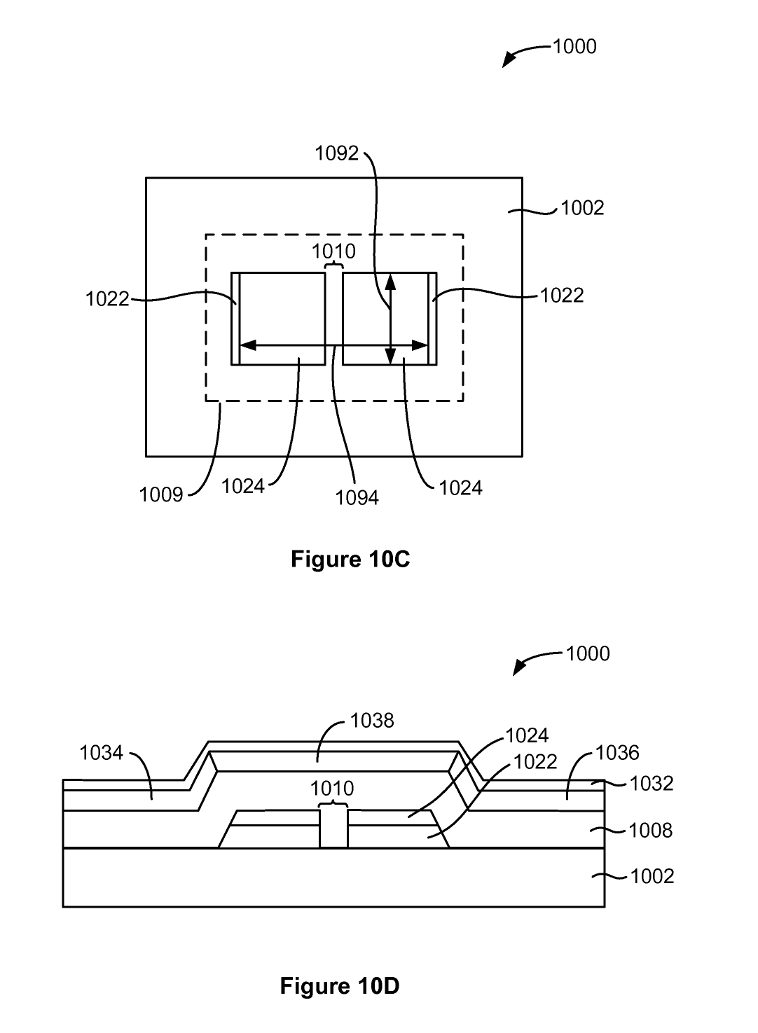

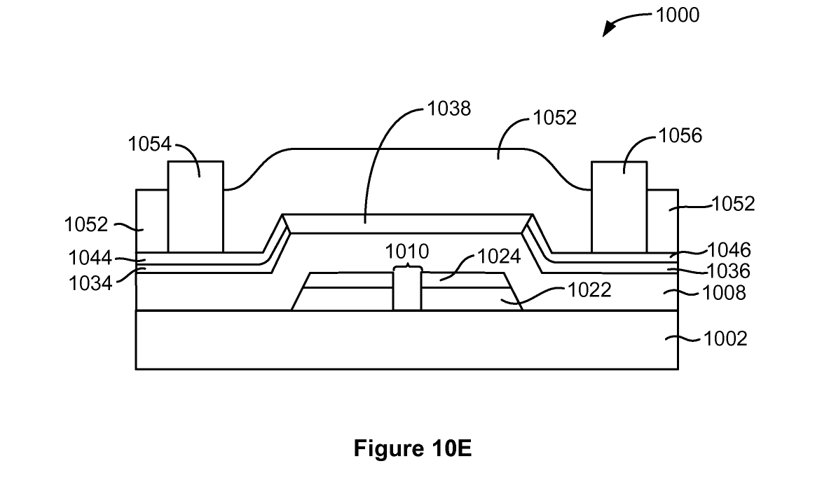

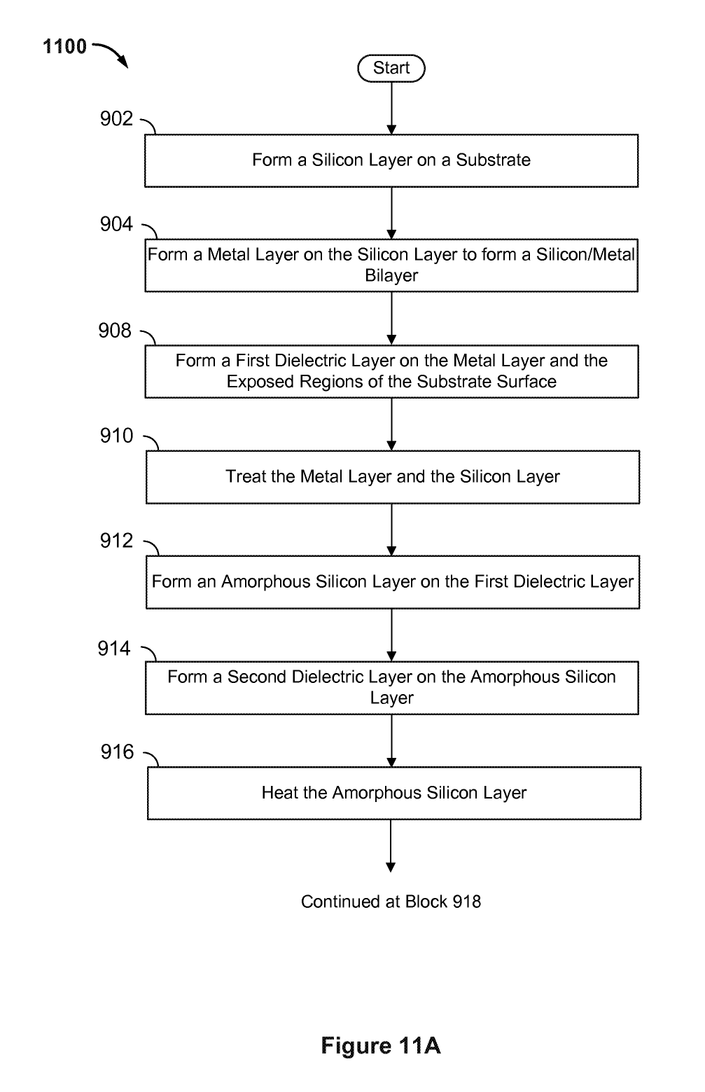

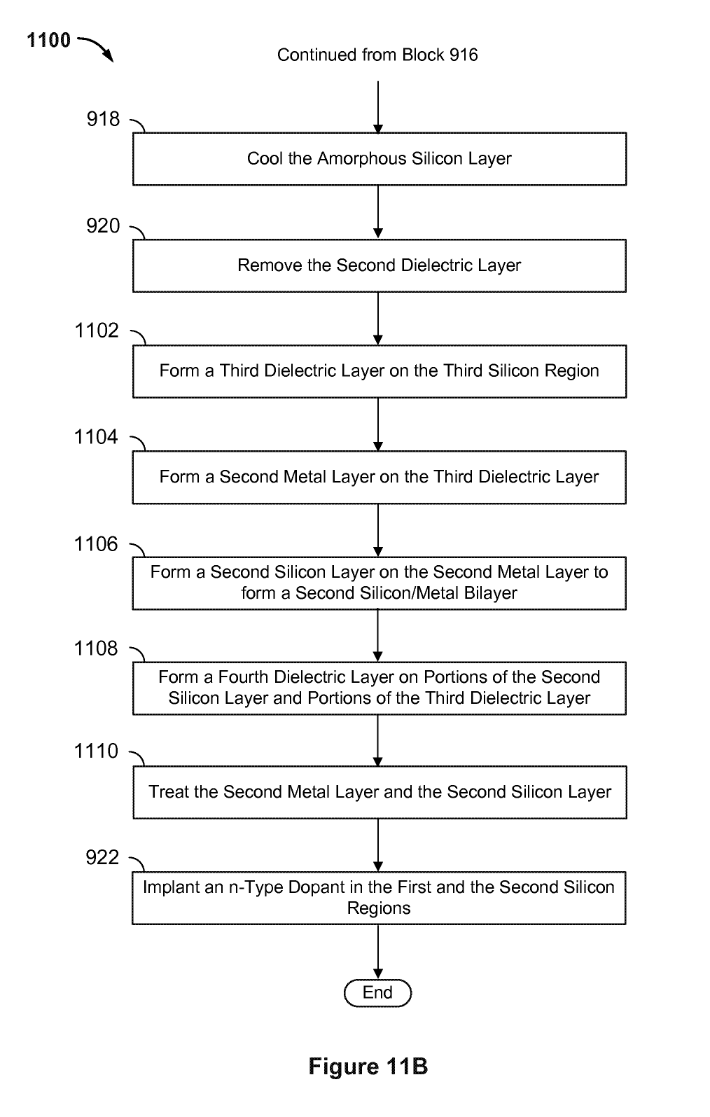

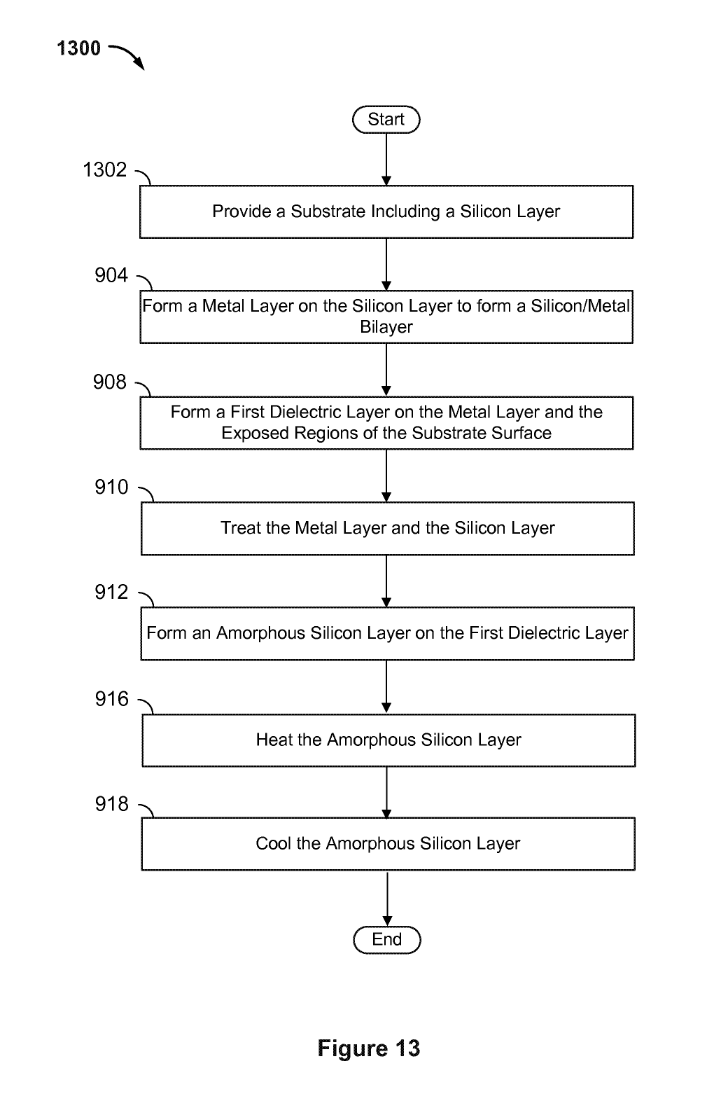

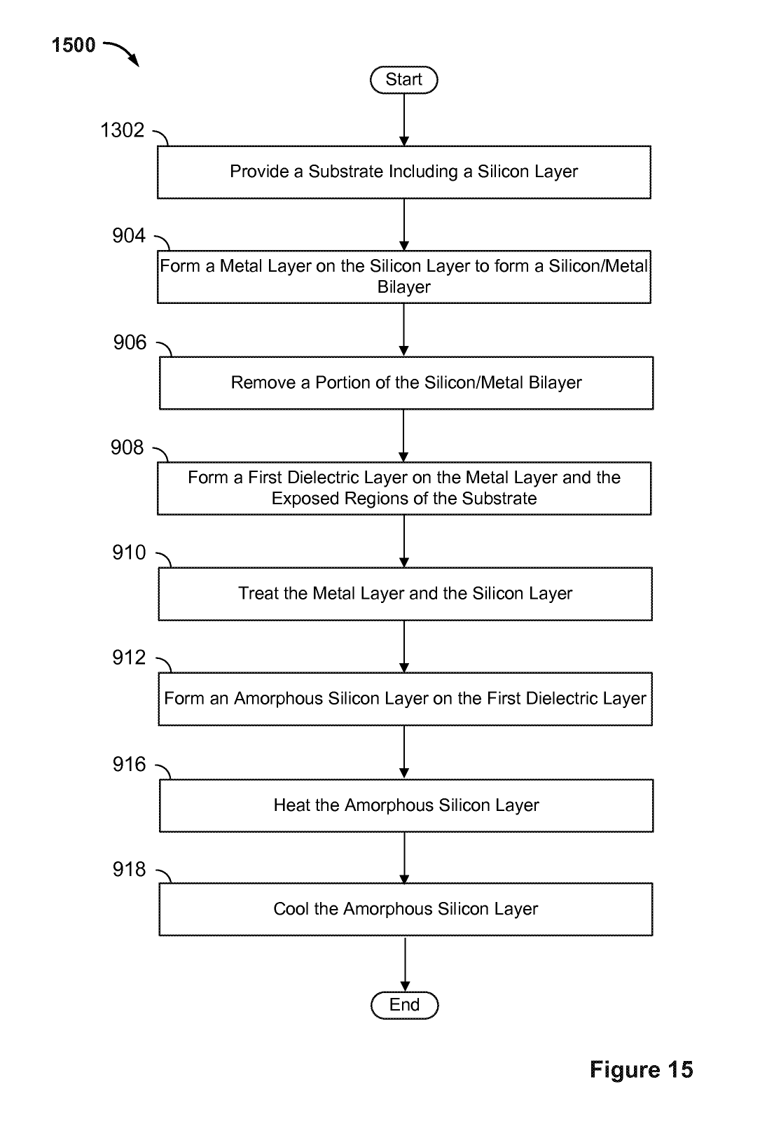

FIGS. 9A and 9B show an example of a flow diagram illustrating a manufacturing process for a thin film transistor device. FIGS. 10A-10E show examples of schematic illustrations of various stages in a method of fabricating a thin film transistor device. A variation of the manufacturing process shown in FIGS. 9A and 9B is described in the example of a flow diagram shown in FIGS. 11A and 11B. Another manufacturing process for a TFT device is described in the example of a flow diagram shown in FIG. 13. Yet another manufacturing process for a TFT device is described in the example of a flow diagram shown in FIG. 15.

Referring to FIG. 9A, at block 902 of the method 900, a silicon layer is formed on a substrate. The substrate may be any number of different substrate materials, including transparent materials and non-transparent materials. In some implementations, the substrate is silicon, silicon-on-insulator (SOI), a glass (for example, a display glass or a borosilicate glass), a flexible plastic, or a metal foil. In some implementations, the substrate on which the TFT device is fabricated can vary in size from a few microns to hundreds of millimeters.

In some implementations, a surface of the substrate on which the TFT device is fabricated includes a buffer layer. The buffer layer may serve as an insulation surface. In some implementations, the buffer layer is an oxide, such as silicon oxide (SiO₂) or aluminum oxide (Al₂O₃). In some implementations, the buffer layer may be about 100 to 1000 nanometers (nm) thick.

The silicon layer is formed on a region of the substrate surface, leaving regions of the substrate surface exposed. The silicon layer may be formed by a number of different techniques, including CVD processes, PECVD processes, low pressure chemical vapor deposition (LPCVD) processes, PVD processes, and liquid phase epitaxy processes. PVD processes include pulsed laser deposition (PLD) and sputter deposition. The silicon layer may include amorphous silicon, polycrystalline silicon, or single crystal silicon, depending on the formation technique. In some implementations, the silicon layer may be about 50 to 200 nm thick. In some implementations, the silicon layer may be thick enough to provide silicon to form a silicide and a gap in a treatment process (described below).

At block 904, a metal layer is formed on the silicon layer, forming a silicon/metal bilayer. The metal layer may be a metal that forms a silicide. For example, the metal may be titanium (Ti), nickel (Ni), molybdenum (Mo), tantalum (Ta), tungsten (W), platinum (Pt), or cobalt (Co). The metal layer may be formed using deposition processes including PVD processes, CVD processes, and atomic layer deposition (ALD) processes. In some implementations, the metal layer may be about 50 to 100 nm thick.

In some implementations, the region of the substrate surface on which the silicon and metal bilayer is formed may be defined by a photoresist or other mask material prior to deposition. In some other implementations, the silicon layer and/or the metal layer may be formed on a larger area of the substrate surface that includes the region of the substrate surface. In these other implementations, the silicon layer and/or the metal may be patterned with photoresists after they are formed. The silicon layer and/or the metal layer may then be etched to remove a portion of the silicon layer and the metal layer from the substrate surface, leaving the silicon layer and the metal layer on the region of the substrate surface.

At block 906, a portion of the silicon/metal bilayer is removed. Removing the silicon/metal bilayer may involve patterning operations including photolithography and etching. These operations may remove a portion of the silicon/metal bilayer from the substrate surface to expose a portion of the substrate surface. The portion of the silicon/metal bilayer that is removed may be filled with a dielectric that aids in supporting an overlying dielectric layer.

At block 908, a first dielectric layer is formed on the metal layer and the exposed regions of the substrate surface including the portion of the substrate surface exposed by the operation at block 906. The first dielectric layer may include a number of different dielectric materials. In some implementations, the first dielectric layer is a silicon dioxide (SiO₂), aluminum oxide (Al₂O₃), hafnium oxide (HfO₂), titanium oxide (TiO₂), silicon oxynitride (SiON), or silicon nitride (SiN) layer. In some other implementations, the first dielectric layer includes two or more layers of different dielectric materials arranged in a stacked structure. The first dielectric layer may be formed using deposition processes including PVD processes, CVD processes including PECVD processes, and ALD processes. In some implementations, the first dielectric layer may be about 50 to 500 nm thick.

FIG. 10A shows an example of a cross-sectional schematic illustration of a TFT device 1000 at this point (for example, up to block 908) in the method 900. The TFT device includes a substrate 1002, a silicon layer 1004, a metal layer 1006, and a first dielectric layer 1008. The first dielectric layer 1008 is generally conformal to the underlying substrate 1002 and structure formed by the silicon layer 1004 and the metal layer 1006. In the depicted example, the first dielectric 1008 fills the volume 1010 where a portion of the bilayer formed by the silicon layer 1004 and the metal layer 1006 were removed at block 906.

Returning to FIG. 9A, at block 910, the metal layer and the silicon layer are treated. During the treatment, the metal layer reacts with the silicon layer to form a silicide layer and a gap between the silicide layer and the first dielectric layer. For example, depending on the metal of the metal layer, a titanium silicide (TiSi₂), nickel silicide (NiSi), molybdenum silicide (MoSi₂), tantalum silicide (TaSi₂), tungsten silicide (WSi₂), platinum silicide (PtSi), or cobalt silicide (CoSi₂) silicide layer may be formed. In some implementations, the reaction of the metal layer with the silicon layer is a self-limiting process in which the reaction stops when the metal layer is consumed. In some implementations, the entire metal layer reacts with the silicon layer. In some implementations, when all of the metal layer is consumed, some silicon that has not reacted with the metal may remain. In some implementations, all of the silicon is converted to a silicide. In some implementations, the entire metal layer reacts with the silicon layer and all of the silicon is converted to a silicide. In some implementations, the treatment may be stopped before all of the metal layer is consumed.

Thus, the thickness of the gap may be controlled by the thickness of the metal layer and/or the thickness of the silicon layer. For example, when Ni is used for the metal layer, about a 1 nm thick layer of Ni will consume about 1.8 nm of silicon, forming a NiSi layer about 2.3 nm thick, resulting in a thickness loss of the Ni and silicon layers of about 0.5 nm (i.e., 2.8 nm-2.3 nm). To form an about 20 nm thick gap, for example, an about 39.2 nm thick layer of Ni on a layer of silicon that is at least about 72 nm thick may be used. In some implementations, the thickness of the gap may be about 10 to 50 nm.

In some implementations, the treatment provides the energy for a reaction between the metal layer and the silicon layer. In some implementations, the treatment may include a heat treatment. The temperature and the duration of the heat treatment depend on the reaction temperature of the metal layer with the silicon layer. In some implementations, the heat treatment may be at about 250° C. to 1000° C. for about 1 minute to about 20 minutes. For example, when Ni is used for the metal layer, the heat treatment may be at about 450° C. for about 10 minutes. In some other implementations, the treatment may include implanting various dopants into the silicon layer via an ion implantation process or roughening the surface of the silicon layer by plasma etching and then diffusing various dopants into the silicon layer.

In some implementations, the gap between the silicide layer and the first dielectric layer may be a vacuum gap. For example, when the first dielectric layer completely covers the silicon layer and the metal layer, when the metal layer reacts with the silicon layer, a vacuum may be formed in the gap. In some other implementations, when the first dielectric layer does not completely cover the silicon layer and the metal layer, the gap may include air, i.e., the gap may be an air gap.

FIG. 10B shows an example of a cross-sectional schematic illustration of the TFT device 1000 at this point (for example, up to block 910) in the method 900. The TFT device 1000 includes a silicide layer 1022 and a gap 1024. In the depicted example, the gap 1024 is between the silicide layer 1022 and the substrate 1002. The gap is divided in two by the volume 1010 filled by the first dielectric layer 1008.

In the depicted example, the metal layer 1006 and the silicon layer 1004 depicted in FIG. 10A are both consumed in FIG. 10B. In some other implementations (not depicted), a portion of the silicon layer 1004 depicted in FIG. 10A can remain, disposed between the silicide layer 1022 and the substrate 1002. In some other implementations (not depicted), a portion of the metal layer 1006 can remain disposed between the gap 1024 and the first dielectric layer 1008.

FIG. 10C shows an example of a top-down schematic illustration of the TFT device 1000 at this point (for example, up to block 910) in the method 900. For clarity, the top-down view of the TFT device 1000 shown in FIG. 10C does not show the first dielectric layer 1008. The TFT device 1000 includes the substrate 1002, the silicide layer 1022, and the gap 1024. The exposed regions of the substrate surface on which the first dielectric layer 1008 is formed are indicated by a dashed line 1009; any of the exposed substrate surface within 1009 may include the first dielectric layer 1008. A dimension 1092 of the gap 1024 may be about 50 nm to tens of microns, in some implementations. A dimension 1094 of the TFT device 1000 may about 50 nm to a few millimeters or about a few microns to tens of microns, in some implementations.

In some implementations, the volume 1010 serves to provide support against atmospheric pressure pushing against the first dielectric layer 1008. For example, when the gap 1024 is a vacuum gap and the TFT device is in an environment at standard atmospheric pressure, the pressure on the gap 1024 tending to cause the gap to collapse can be about 101,325 pascals (Pa) or about 1 atmosphere (atm). The pressure on the gap 1024 tending to cause the gap to collapse may push the first dielectric layer 1008 overlying the gap 1024 into contact with the underlying silicide layer 1022. Depending on the thickness and the rigidity of the first dielectric layer 1008, the atmospheric pressure might be sufficient to cause the gap 1024 to collapse if the volume 1010 filled with the first dielectric layer 1008 was not present. Thus, the volume 1010 filled with the first dielectric layer 1008 may aid in preventing the gap 1024 from collapsing when the first dielectric layer is thin and/or flexible.

While shown as a bar of the first dielectric layer 1008 that divides the gap 1024 into two, the volume 1010 filled with the first dielectric layer 1008 may be in any number of different configurations. In some implementations, the volume 1010 filled with the first dielectric layer may include multiple bars that are substantially parallel to each other and to the dimension 1092 shown in FIG. 10C. In some implementations, the volume 1010 may include one or more bars that are substantially parallel to each other and to the dimension 1094 shown in FIG. 10C. In some implementations, the volume 1010 filled with the first dielectric layer may be a cylindrical post in the center of silicide layer 1022 and the gap 1024 or a number of symmetrically arranged cylindrical posts in the silicide layer 1022 and the gap 1024. The posts may be arranged in other patterns, and the posts may have different cross-sections, such as triangular, hexagonal, or square cross-sections, and are not limited to the cylindrical cross-sections. In some other implementations, the volume filled with the first dielectric layer may be a honeycomb structure.

At block 912, an amorphous silicon layer is formed on the first dielectric layer. The amorphous silicon layer may be formed by a number of different techniques, including CVD processes, PECVD processes, LPCVD processes, PVD processes, and liquid phase epitaxy processes. In some implementations, the amorphous silicon layer may be about 50 to 150 nm thick, such as about 100 nm thick. The amorphous silicon layer can include three regions: a third silicon region overlying the gap and a first silicon region and a second silicon region overlying the substrate on either side of the gap such that the third silicon region is between the first silicon region and the second silicon region. The third silicon region may form the channel region of the TFT device. The first and the second silicon regions may form the source region and the drain region, respectively, or vice versa, of the TFT device.

At block 914, a second dielectric layer is formed on the amorphous silicon layer. The second dielectric layer may be any number of different dielectric materials. In some implementations, the second dielectric layer is the same dielectric material as the first dielectric layer, including SiO₂, Al₂O₃, HfO₂, TiO₂, SiON, and SiN. The second dielectric layer may be formed using deposition processes, including PVD processes, CVD processes, and ALD processes. In some implementations, the second dielectric layer may be about 10 to 100 nm thick, such as about 10 to 50 nm thick.

At block 916, the amorphous silicon layer is heated. The amorphous silicon layer may be heated with any number of different heating methods. In some implementations, the amorphous silicon layer melts or partially melts; i.e., the amorphous silicon layer may be heated to about 1414° C., the melting temperature of silicon. In some implementations, the amorphous silicon layer is heated with an excimer laser. For example, a xenon chloride (XeCl) excimer laser may be used to irradiate the second dielectric layer and heat the underlying amorphous silicon layer. The laser energy density may be about 280 to 380 millijoules per square centimeter (mJ/cm²), such as about 320 mJ/cm². The second dielectric, which overlies the amorphous silicon layer, may serve to prevent evaporation of the amorphous silicon layer during the heating process.

At block 918, the amorphous silicon layer is cooled. The first silicon region and the second silicon region, both overlying the substrate, cool, in part, via heat conduction to the underlying substrate. The first silicon region and the second silicon region may cool rapidly due to this heat conduction. For example, the first silicon region and the second silicon region may cool at a rate on the order of about 10⁸° C. per second, in some implementations. The third silicon region, overlying the gap, cools, in part, via heat conduction though the first silicon region and the second silicon region; lesser heat conduction may occur though the gap, as the thermal conductivity of air or a vacuum of the gap is low. Thus, the third silicon region may cool slowly due to the gap.

Due to the slow heat conduction from the third silicon region, the third silicon region may crystallize as a single silicon grain (i.e., a single crystal of silicon) or large silicon grains. For example, due to the heat conduction from the third silicon region, larger silicon grains (for example, about 4 microns in length) may grow, spanning the third silicon region from the first to the second silicon regions. Due to the faster heat conduction from the first and the second silicon regions, the first and the second silicon regions may include amorphous silicon or small silicon grains. For example, small silicon grains may be nanometer sized grains.

The configuration of a volume in the gap that is filled in with the first dielectric layer (for example, volume 1010 in FIG. 10C) may affect the rate of heat conduction from the third silicon region. Thus, the configuration of a volume may be tailored to form a specific silicon microstructure in the third silicon region. For example, some configurations of the volume filled with the first dielectric layer, such as bars of the first dielectric layer that are substantially parallel to each other and to the dimension 1094 shown in FIG. 10C, may conduct heat from the third silicon region in a manner that results in single crystal of silicon.

Further detail regarding recrystallizing an amorphous silicon layer to form a TFT device may be found in “A Poly-Si TFT Fabricated by Excimer Laser Recrystallization on Floating Active Structure,” Cheon-Hong Kim et al., IEEE Electron Device Letters, Vol. 23, No. 6, pp. 315-317, June 2002, which is herein incorporated by reference.

FIG. 10D shows an example of a cross-sectional schematic illustration of the TFT device 1000 at this point (for example, up to block 918) in the method 900. As described above with respect FIG. 10B, the TFT device 1000 includes the silicide layer 1022 and the first dielectric layer 1008 overlying the substrate 1002, with the gap 1024 between the silicide layer 1022 and the first dielectric layer 1008. Three silicon regions overlie the first dielectric layer 1008: a first silicon region 1034, a second silicon region 1036, and a third silicon region 1038. A second dielectric layer 1032 conformally overlies the first, second, and third silicon regions 1034, 1036, and 1038.

The third silicon region 1038 may include a single silicon grain or silicon grains. The first silicon region 1034 and the second silicon region 1036 may include amorphous silicon or silicon grains smaller than the single silicon grain or silicon grains in the third silicon region 1038. While the TFT device 1000 shown in FIG. 10D has clear boundaries between the first silicon region 1034, the second silicon region 1036, and the third silicon region 1038, an actual TFT device may include a gradual transition from the larger grain sizes in the third silicon region 1038 to the smaller grain sizes in the first and the second silicon regions 1034 and 1036, for example. The grain sizes in each silicon region and the boundary of each region depend on the heat conduction out of the amorphous silicon layer.

At block 920, the second dielectric layer is removed. Wet or dry etching processes may be used to remove the second dielectric layer 1032.

At block 922, an n-type dopant is implanted in the first and the second silicon regions. In some implementations, a mask may be used to prevent the dopant from being implanted in the third silicon region. For example, phosphorus (P) may be implanted in the first and second silicon regions. The P dopant may be implanted to a dose of about 5×10²⁰ atoms per centimeter squared (cm²), for example. Other n-type dopants may be implanted using an appropriate method to an appropriate dose, as know by a person having ordinary skill in the art.

At block 924, a third dielectric layer is formed on the first silicon region, the second silicon region, and the third silicon region. The third dielectric layer may be any number of different dielectric materials. In some implementations, the third dielectric layer is the same dielectric material as the first dielectric layer, including SiO₂, Al₂O₃, HfO₂, TiO₂, SiON, and SiN. The third dielectric layer may be formed using deposition processes including PVD processes, CVD processes, and ALD processes. In some implementations, the third dielectric layer may be about 50 to 500 nm thick. In some implementations, the third dielectric layer acts as a passivation insulator. A passivation insulator can serve as a layer that protects the TFT device from the external environment.

At block 926, portions of the third dielectric layer are removed to expose the first silicon region and the second silicon region. Photoresists with wet or dry etching processes may be used to expose the first silicon region and the second silicon region.

At block 928, contacts to the first silicon region and the second silicon region are formed. The contacts may be any number of different metals, including aluminum (Al), copper (Cu), molybdenum (Mo), tantalum (Ta), chromium (Cr), neodymium (Nd), tungsten (W), titanium (Ti), and an alloy containing any of these elements. In some implementations, the contacts include two or more different metals arranged in a stacked structure. The contacts also may be a conductive oxide, such as indium tin oxide (ITO). The contacts may be formed using deposition processes including PVD processes, CVD processes, and ALD processes.

FIG. 10E shows an example of a cross-sectional schematic illustration of the TFT device 1000 at this point (for example, at the end of the method 900). The TFT device includes the silicide layer 1022 and the first dielectric layer 1008 overlying the substrate 1002, with the gap 1024 between the silicide layer 1022 and the first dielectric layer 1008. Three silicon regions overlie the first dielectric layer 1008: a first silicon region 1034, a second silicon region 1036, and a third silicon region 1038. The TFT device 1000 further includes an n-doped portion 1044 of the first silicon region 1034 and an n-doped portion 1046 of the second silicon region 1036. A third dielectric layer 1052 overlies the n-doped portion 1044, the third silicon region 1038, and the n-doped portion 1046. A first contact 1054 and a second contact 1056 penetrate the third dielectric layer 1052 to contact the n-doped region 1044 and the n-doped region 1046, respectively.

For the TFT device 1000, the silicide layer 1022 can serve as a gate, making the TFT device 1000 a bottom-gate TFT device. The third silicon region 1038 can serve as a channel region of the TFT device 1000 with the n-doped portion 1044 of the first silicon region 1034 serving as a source region and the n-doped portion 1046 of the second silicon region 1036 serving as a drain region. In some implementations, the length of the channel region (i.e., the distance between the first silicon region 1034 and the second silicon region 1036) may be short, enabling improved performance of the TFT device 1000. In some implementations, the width of the channel region (i.e., the dimension of the third silicon region 1038 that extends into the page) may be large, enabling the TFT device to accommodate a large current flow between the n-doped portion 1044 of the first silicon region 1034 and the n-doped portion 1046 of the second silicon region 1036. The length and the width of the third silicon region 1038 may be greater than about 3 microns (for example, about 3 microns to 4 microns) for both the length and the width, in some implementations. In some other implementations, the length and the width of the third silicon region 1038 may be less than about 3 microns (for example, about 1 micron to 2 microns, or even smaller) for both the length and the width.

In some implementations, the gap 1024 and the first dielectric layer 1008 underlying the third silicon region 1038 together serve as the gate insulator. The third dielectric layer 1052 can serve as a passivation insulator. As described above, a volume 1010 filled by the first dielectric layer 1008 that divides the gap 1024 can serve as a structural support feature for the portion of the first dielectric layer 1008 that overlies the gap 1024.

While FIGS. 10A-10E show examples of schematic illustrations of various stages in a method of fabricating a TFT device, various modifications can be made according to the desired implementation. For example, while the silicon layer 1004 and the metal layer 1006 are shown as planar layers of material in FIG. 10A, is some implementations, the silicon layer 1004 and/or the metal layer 1006 may be contoured. The silicon layer 1004 and/or the metal layer 1006 being contoured may produce a gap 1024 having a variable thickness across the length of the gap, in some implementations. A variable thickness gap may affect the rate of heat conduction from the third silicon region. Thus, in some implementations, a variable thickness gap may be tailored to form a specific silicon microstructure in the third silicon region. For example, the silicon layer 1004 may have a triangular cross-section and the metal layer 1006 may conform to the underlying silicon layer 1004. As another example, the silicon layer 1004 may be a planar layer and the metal layer 1006 may have a triangular cross section.

FIGS. 11A and 11B show an example of a flow diagram illustrating a manufacturing process for a thin film transistor device. The method 1100 shown in FIGS. 11A and 11B is similar to the method 900 shown in FIGS. 9A and 9B, with some process operations shown in FIGS. 9A and 9B being omitted and further process operations being added. Implementations of the method 1100 may be used to fabricate a top-gate or a dual-gate TFT device, for example.

Referring to FIG. 11A, the method 1100 starts with process operations described with respect to the method 900. At block 902 of the process 1100, a silicon layer is formed on a substrate. At block 904, a metal layer is formed on the silicon layer, forming a silicon/metal bilayer. As described above with respect to FIGS. 9A and 9B, the metal and silicon layers will eventually be reacted to form a silicide layer. At block 908, a first dielectric layer is formed on the metal layer and the exposed regions of the substrate surface. At block 910, the metal layer and the silicon layer are treated. As described above with respect to FIGS. 9A and 9B, the treatment provides energy for a reaction between the metal layer and the silicon layer, forming a silicide layer and a gap. At block 912, an amorphous silicon layer is formed on the first dielectric layer. The amorphous silicon layer can include three regions: a third silicon region overlying the gap and a first silicon region and a second silicon region overlying the substrate on either side of the gap such that the third silicon region is between the first silicon region and the second silicon region. At block 914, a second dielectric layer is formed on the amorphous silicon layer. At block 916, the amorphous silicon layer is heated. At block 918, the amorphous silicon layer is cooled. Due to the gap, the third silicon region may cool at a slower rate relative to the first silicon region and the second silicon region. At block 920, the second dielectric layer is removed. Additional details of blocks 902-920 are described above with respect to FIGS. 9A and 9B.

The method 1100 then continues at block 1102, in which a third dielectric layer is formed on the third silicon region. The third dielectric layer may be any number of different dielectric materials. In some implementations, the third dielectric layer is the same dielectric material as the first dielectric layer, including SiO₂, Al₂O₃, HfO₂, TiO₂, SiON, and SiN. The third dielectric layer may be formed using deposition processes, including PVD processes, CVD processes, and ALD processes. In some implementations, the third dielectric layer may be about 10 to 75 nm thick.

At block 1104, a second metal layer is formed on the third dielectric layer. The second metal layer may be a metal that forms a silicide. For example, the metal may be Ti, Ni, Mo, Ta, W, Pt, or Co. The second metal layer may be formed using deposition processes including PVD processes, CVD processes, and ALD processes. In some implementations, the second metal layer may be about 50 to 100 nm thick.

At block 1106, a second silicon layer is formed on the second metal layer to form a second silicon/metal bilayer. The second silicon layer may be formed by a number of different techniques. For example, the second silicon layer may be formed using CVD processes, PECVD processes, LPCVD processes, PVD processes, or liquid phase epitaxy processes. The second silicon layer may include amorphous silicon, polycrystalline silicon, or single crystal silicon, depending on the formation technique. In some implementations, the second silicon layer may be about 50 to 200 nm thick. In some implementations, the silicon may be thick enough to provide silicon to form a silicide and a gap in a treatment process.

At block 1108, a fourth dielectric layer is formed on portions of the second silicon layer and portions of the third dielectric layer. For example, the fourth dielectric layer may be formed on the peripheral edges of the second silicon layer and on the portions of the third dielectric layer not covered by the second metal layer and the second silicon layer. As discussed further below, the fourth dielectric layer may serve as a support during formation of a second gap. The portions of the second silicon layer and third dielectric layer on which the fourth dielectric layer is formed can depend in part on the desired characteristics of the second gap. The fourth dielectric layer may be any number of different dielectric materials. In some implementations, the fourth dielectric layer is the same dielectric material as the first dielectric layer, including SiO₂, Al₂O₃, HfO₂, TiO₂, SiON, and SiN. The fourth dielectric layer may be formed using deposition processes including PVD processes, CVD processes, and ALD processes. In some implementations, the fourth dielectric layer may be about 100 to 250 nm thick.

At block 1110, the second metal layer and the second silicon layer are treated, similar to block 910. During the treatment, the second metal layer reacts with the second silicon layer to form a second silicide layer and a second gap between the second silicide layer and the third dielectric layer. In some implementations, the reaction of the second metal layer with the second silicon layer is a self-limiting process in which the reaction stops when the second metal layer is consumed. In some implementations, the entire second metal layer reacts with the second silicon layer. In some implementations, when all of the second metal layer is consumed, some silicon that has not reacted with the metal may remain. In some implementations, all of the silicon is converted to a silicide. In some implementations, the entire second metal layer reacts with the second silicon layer and all of the silicon is converted to a silicide. In some implementations, the treatment may be stopped before all of the second metal layer is consumed. Thus, the thickness of the second gap may be controlled by the thickness of the second metal layer and/or the thickness of the second silicon layer. In some implementations, the thickness of the second gap may be about 10 to 50 nm. In some implementations, the thickness of the gap formed at block 910 may be the same as the thickness of the second gap. In some other implementations, the thickness of gap formed at block 910 may be different than the thickness of the second gap.

In some implementations, the treatment may include a heat treatment. The temperature and the duration of the heat treatment at block 1110 depend on the reaction temperature of the second metal layer with the second silicon layer. In some implementations, the heat treatment may be at about 250° C. to 1000° C. for about 1 minute to about 20 minutes. For example, when Ni is used for the second metal layer, the heat treatment may be at about 450° C. for about 10 minutes. In some other implementations, the treatment may include implanting various dopants into the silicon layer via an ion implantation process or roughening the surface of the silicon layer by plasma etching and then diffusing various dopants into the silicon layer.

The fourth dielectric layer on portions of the second silicon layer and portions of the third dielectric layer may serve as a support for the second silicon layer as the second silicon layer reacts with the second metal layer to form a second gap. In some implementations, the second gap between the second silicide layer and the third dielectric layer may be a vacuum gap. For example, when the fourth dielectric layer completely covers the edges of the second silicon layer and the second metal layer, when the second metal layer reacts with the second silicon layer, a vacuum may be formed in the second gap. In some other implementations, when the fourth dielectric layer does not completely cover the edges of the second silicon layer and the second metal layer, the second gap may include air. If the second gap is a vacuum gap, the fourth dielectric layer may support the second silicide layer that is formed against the pressure on the second gap tending to push the second silicide layer into contact with the third dielectric layer.

The method 1100 continues with a process operation described above with respect to the method 900. At block 922, an n-type dopant is implanted in the first and the second silicon regions. The third dielectric layer, the second silicide layer, and the fourth dielectric layer may act as a mask to prevent the dopant from being implanted in the third silicon region. For example, phosphorus (P) may be implanted in the first and second silicon regions. The P dopant may be implanted to a dose of about 5×10²⁰ atoms per centimeter squared (cm²), for example. Other n-type dopants may be implanted using an appropriate method to an appropriate dose.

In some implementations of the method 1100, the operation at block 906 of the method 900 is not performed. Thus, in some implementations of the method 1100, after the metal layer and the silicon layer are treated to form the silicide layer and the gap at block 910, if the gap is a vacuum gap, the first dielectric layer may be thick and/or rigid enough such that the gap does not collapse and push the first dielectric layer overlying the gap into contact with the silicide layer.

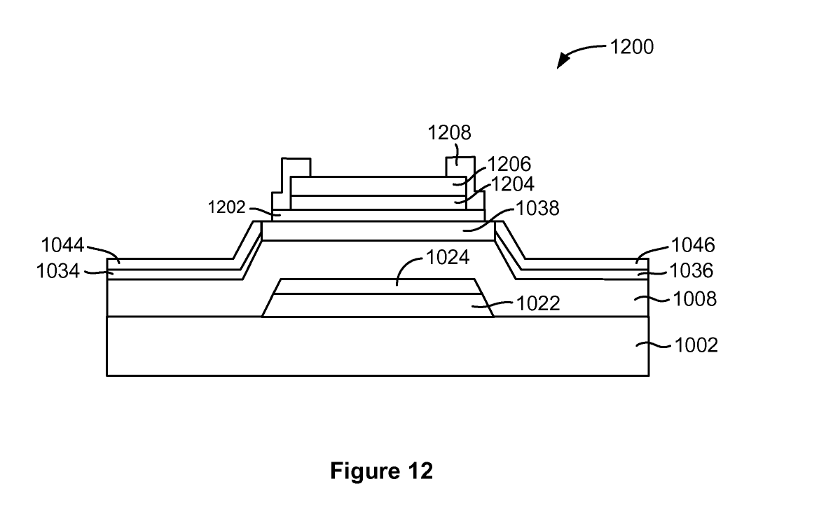

FIG. 12 shows an example of a cross-sectional schematic illustration of a partially fabricated thin film transistor device. The partially fabricated TFT device 1200 shown in FIG. 12 includes an example of a structure that may be produced by the method 1100. The partially fabricated TFT device includes the silicide layer 1022 and the first dielectric layer 1008 overlying the substrate 1002, with the gap 1024 between the silicide layer 1022 and the first dielectric layer 1008. Three silicon regions overlie the first dielectric layer 1008: a first silicon region 1034, a second silicon region 1036, and a third silicon region 1038. The TFT device 1200 also includes an n-doped portion 1044 of the first silicon region 1034 and an n-doped portion 1046 of the second silicon region 1036. The partially fabricated TFT device 1200 further includes a second silicide layer 1206 overlying a third dielectric layer 1202 on the third silicon region 1038, with a second gap 1204 between the second silicide layer 1206 and the third dielectric layer 1202. A fourth dielectric layer 1208 can serve as a support for the second silicide layer 1206.

In some implementations, when fabrication of the partially fabricated TFT device 1200 is complete, the second silicide layer 1206 can serve as a gate, making the TFT device 1200 a top-gate TFT device. The third silicon region 1038 can serve as a channel region of the TFT device 1200 with the n-doped portion 1044 of the first silicon region 1034 serving as a source region and the n-doped portion 1046 of the second silicon region 1036 serving as a drain region. In some implementations, the second gap 1204 and the third dielectric layer 1202 overlying the third silicon region 1038 together serve as the gate insulator.

In some other implementations, when fabrication of the partially fabricated TFT device 1200 is complete, both the silicide layer 1022 and the second silicide layer 1206 can serve as gates, making the TFT device 1200 a dual-gate TFT device. The third silicon region 1038 can serve as a channel region of the TFT device 1200 with the n-doped portion 1044 of the first silicon region 1034 serving as a source region and the n-doped portion 1046 of the second silicon region 1036 serving as a drain region. In some implementations, the gap 1024 and the first dielectric layer 1008 underlying the third silicon region 1038 together serve as the gate insulator for the bottom-gate (for example, the silicide layer 1022), and the second gap 1204 and the third dielectric layer 1202 overlying the third silicon region 1038 together serve as the gate insulator for the top-gate (for example, the second silicide layer 1206).

To complete the fabrication of the TFT device, the method 1100 may continue with process operations similar to the process operations described above with respect to the method 900. For example, a fifth dielectric layer may be formed on the first silicon region, the second silicon region, the fourth dielectric layer, and the second silicide layer, similar to block 924. The fifth dielectric layer may serve as a passivation insulator. Portions of the fifth dielectric layer may be removed to expose the first and the second silicon regions, similar to block 926. Further, a portion of the fifth dielectric layer may be removed to expose the second silicide layer. Contacts to the first and the second silicon regions may be formed as described with respect to block 928. Further, a contact to the second silicide layer may be formed.

FIG. 13 shows an example of a flow diagram illustrating a manufacturing process for a thin film transistor device. The method 1300 shown in FIG. 13 includes some process operations described with respect to the method 900 shown in FIGS. 9A and 9B.

At block 1302, a substrate including a silicon layer is provided. The substrate may be any number of different substrate materials, including transparent materials and non-transparent materials. In some implementations, the substrate is silicon, silicon-on-insulator (SOI), a glass (for example, a display glass or a borosilicate glass), a flexible plastic, or a metal foil. In some implementations, the substrate on which the TFT device is fabricated has dimensions of a few microns to hundreds of microns. The silicon layer on the substrate may include amorphous silicon, polycrystalline silicon, or single crystal silicon, depending on the formation technique. In some implementations, the silicon layer may be about 50 to 200 nm thick. In some implementations, the silicon may be thick enough to provide silicon to form a silicide and a gap in a treatment process.

The method 1300 continues with process operations described above with respect to the method 900. At block 904, a metal layer is formed on the silicon layer, forming a silicon/metal bilayer. As described above with respect to FIGS. 9A and 9B, the metal and silicon layers will eventually be reacted to form a silicide layer. At block 908, a first dielectric layer is formed on the metal layer and the exposed regions of the substrate surface. At block 910, the metal layer and the silicon layer are treated. As described above with respect to FIGS. 9A and 9B, the treatment provides the energy for a reaction between the metal layer and the silicon layer, forming a silicide layer and a gap. At block 912, an amorphous silicon layer is formed on the first dielectric layer. The amorphous silicon layer can include three regions: a third silicon region overlying the gap and a first silicon region and a second silicon region overlying the substrate on either side of the gap such that the third silicon region is between the first silicon region and the second silicon region. At block 916, the amorphous silicon layer is heated. At block 918, the amorphous silicon layer is cooled. Due to the gap, the third silicon region may cool at a slower rate relative to the first silicon region and the second silicon region. Additional details of some implementations of blocks 904, 908, 910, 912, 916, and 918 are described above with respect to FIGS. 9A, 9B, 11A and 11B.

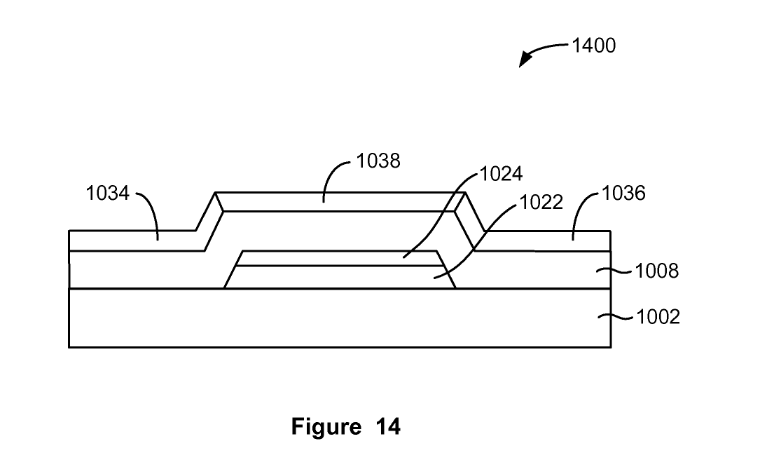

FIG. 14 shows an example of a cross-sectional schematic illustration of a partially fabricated thin film transistor device. The partially fabricated TFT device 1400 shown in FIG. 14 is an example of a structure that may be produced by the method 1300. The partially fabricated TFT device includes the silicide layer 1022 and the first dielectric layer 1008 overlying the substrate 1002, with the gap 1024 between the silicide layer 1022 and the first dielectric layer 1008. Three silicon regions overlie the first dielectric layer 1008: a first silicon region 1034, a second silicon region 1036, and a third silicon region 1038.

To complete the fabrication of the TFT device, the method 1300 may continue with the process operations described above with respect to the method 900. For example, an n-type dopant may be implanted in the first and the second silicon regions, as described with respect to block 922. The n-doped portions of the first silicon region 1034 and the second silicon region 1036 of the TFT device 1400 can serve as a source region and a drain region, respectively, with the third silicon region 1038 serving as a channel region. In some implementations, the gap 1024 and the first dielectric layer 1008 underlying the third silicon region 1038 together serve as the gate insulator. A dielectric layer may be formed on the first, the second, and the third silicon regions as described with respect to block 924. The dielectric layer may serve as a passivation insulator. Portions of the dielectric layer may be removed to expose the first and the second silicon regions as described with respect to block 926. Contacts to the first and the second silicon regions may be formed as described with respect to block 928.

In some implementations of the method 1300, the operation at block 906 of the method 900 is not performed. Thus, in some implementations of the method 1300, after the metal layer and the silicon layer are treated to form the silicide layer and the gap at block 910, the first dielectric layer is thick and/or rigid enough such that the atmospheric pressure may not cause the gap the collapse and push the first dielectric layer into contact with the silicide layer. A TFT device fabricated with the method 1300 may be used as an absolute pressure sensor, as described further below.

FIG. 15 shows an example of a flow diagram illustrating a manufacturing process for a thin film transistor device. The method 1500 shown in FIG. 15 includes some process operations described with respect to the method 900 shown in FIGS. 9A and 9B and the method 1300 shown in FIG. 13.

The method 1500 starts with block 1302, as described above with respect to the method 1300. At block 1302, a substrate including a silicon layer is provided. The method 1500 continues with process operations described above with respect to the method 900. At block 904, a metal layer is formed on the silicon layer, forming a silicon/metal bilayer. As described above with respect to FIGS. 9A and 9B, the metal and silicon layers may be reacted to form a silicide layer. At block 906, a portion of the metal layer and the silicon layer is removed. As described above with respect to FIGS. 9A and 9B, this volume may be filled with a dielectric layer. At block 908, a first dielectric layer is formed on the metal layer and the exposed regions of the substrate surface. At block 910, the metal layer and the silicon layer are treated. As described above with respect to FIGS. 9A and 9B, the treatment provides the energy for a reaction between the metal layer and the silicon layer, forming a silicide layer and a gap. At block 912, an amorphous silicon layer is formed on the first dielectric layer. The amorphous silicon layer can include three regions: a third silicon region overlying the gap and a first silicon region and a second silicon region overlying the substrate on either side of the gap such that the third silicon region is between the first silicon region and the second silicon region. At block 916, the amorphous silicon layer is heated. At block 918, the amorphous silicon layer is cooled. Due to the gap, the third silicon region may cool at a slower rate relative to the first silicon region and the second silicon region. Additional details of some implementations of blocks 904, 906, 908, 910, 912, 916, and 918 are described above with respect to FIGS. 9A, 9B, 11A and 11B.

To complete the fabrication of the TFT device, the method 1500 may continue with the process operations described above with respect to the method 900. For example, an n-type dopant may be implanted in the first and the second silicon regions, as described with respect to block 922. The n-doped portions of the first silicon region and the second silicon region of the TFT device can serve as a source region and a drain region, respectively, with the third silicon region serving as a channel region. In some implementations, the gap and the first dielectric layer underlying the third silicon region together serve as the gate insulator. A dielectric layer may be formed on the first, the second, and the third silicon regions as described with respect to block 924. The dielectric layer may serve as a passivation insulator. Portions of the dielectric layer may be removed to expose the first and the second silicon regions as described with respect to block 926. Contacts to the first and the second silicon regions may be formed as described with respect to block 928.

Variations of the methods 900, 1100, 1300, and 1500 of manufacturing a TFT device may exist. For example, the methods 1100 and 1300 may include removing a portion of a silicon/metal bilayer so that a volume is filled with a dielectric layer. As another example, in the method 1100, implanting the n-type dopant in the first and the second silicon regions at block 922 may occur before forming the third dielectric layer on the third silicon region in block 1102 or somewhere in between one of blocks 1102 to 1110.

As noted above, some implementations of the TFT devices described herein may function as an absolute pressure sensor. An absolute pressure sensor measures the pressure (for example, the atmospheric pressure) relative to perfect vacuum pressure (i.e., 0 Pa, or no pressure). For example, atmospheric pressure is defined as 101,325 Pa at sea level with reference to vacuum, but the atmospheric pressure changes with elevation changes.

In some implementations, the partially fabricated TFT device 1400 shown in FIG. 14 may function as an absolute pressure sensor when fully fabricated. To operate as an absolute pressure sensor, the gap 1024 of the TFT device 1400 includes a vacuum; i.e., the gap 1024 is a vacuum gap. A thickness of a vacuum gap is configured to increase or decrease due to a change in atmospheric pressure.

For example, for the partially fabricated TFT device 1400, a portion of the first silicon region 1034 may serve as a source region, a portion of the second silicon region 1036 may serve as a drain region, and the third silicon region 1038 may serve as a channel region. The gap 1024 and the dielectric layer 1008 together may serve as a gate insulator, and the silicide layer 1022 may serve as the gate. In some implementations, a constant voltage may be applied to the silicide layer 1022 (i.e., the gate), which may keep the TFT device 1400 in the linear region. In some other implementations, a voltage applied to the second silicon region 1036 (i.e., the drain region) also may be applied to the silicide layer 1022 (i.e., the gate), which may keep the TFT device 1400 in the saturation region.

An increase in atmospheric pressure may decrease the gap 1024 thickness; i.e., an increase in atmospheric pressure may push the third silicon region 1038 and the first dielectric layer 1008 underlying the third silicon region 1038 closer to the silicide layer 1022. A decrease in the gap thickness may cause an increase in the gate capacitance (i.e., the oxide capacitance) density. Such an increase in the gate capacitance density when a constant voltage is applied to the silicide layer 1022 leads to a modulation of the drain current. Because the gap 1024 is a vacuum gap, the absolute pressure can be determined by the modulation of the drain-to-source current; i.e., a modulation of the current flow from the second silicon region 1036 (i.e., the drain region) to the first silicon region 1034 (i.e., the source region). Thus, the absolute pressure may be measured as a current though the TFT device 1400.

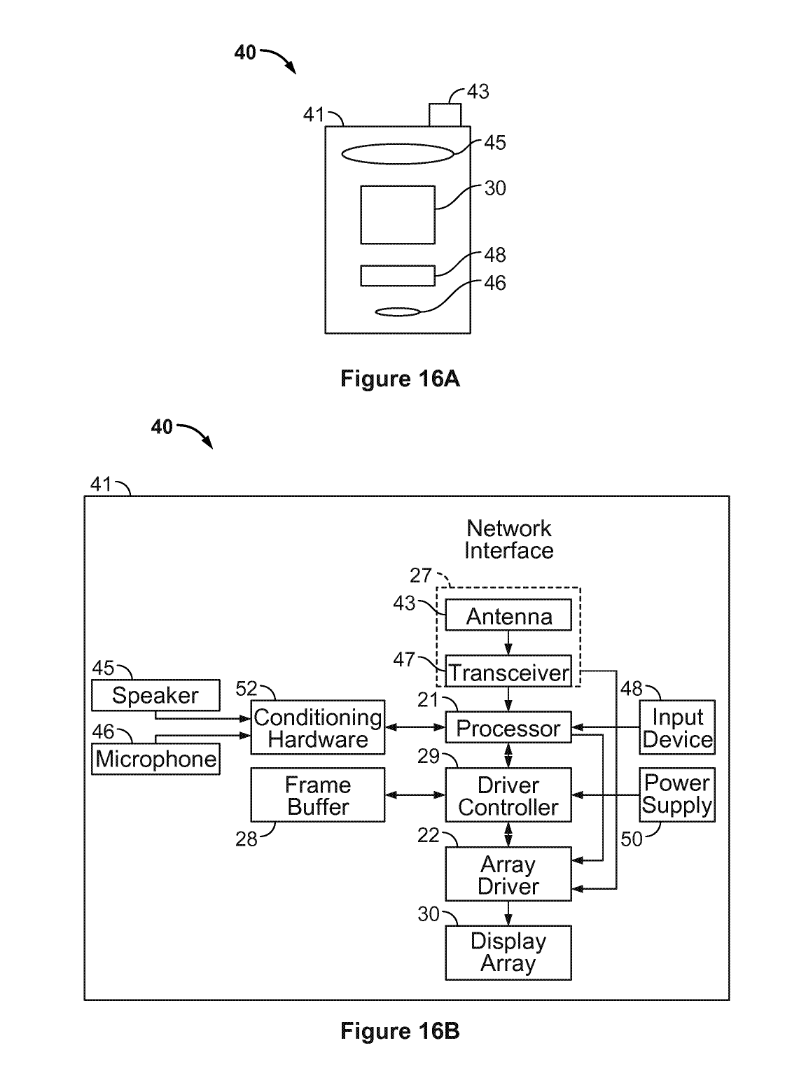

FIGS. 16A and 16B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1× EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method comprising:
providing a substrate having a surface, the substrate including a first silicon layer on a region of the substrate surface, the first silicon layer leaving regions of the substrate surface exposed;
forming a first metal layer on the first silicon layer;
forming a first dielectric layer on the first metal layer and the exposed regions of the substrate surface;
treating the first metal layer and the first silicon layer, wherein the first metal layer reacts with the first silicon layer to form a first silicide layer and a first gap between the first silicide layer and the first dielectric layer;
forming an amorphous silicon layer on the first dielectric layer, the amorphous silicon layer including a first silicon region and a second silicon region overlying the exposed regions of the substrate surface and a third silicon region overlying the first gap, the third silicon region being between the first silicon region and the second silicon region;
heating the amorphous silicon layer; and
cooling the amorphous silicon layer, wherein the first silicon region and the second silicon region cool at a faster rate than the third silicon region.

2. The method of claim 1, wherein the first metal layer includes at least one of titanium, nickel, molybdenum, tantalum, tungsten, platinum and cobalt.

3. The method of claim 1, wherein the third silicon region includes a single silicon grain or silicon grains, and wherein the first and second silicon regions include amorphous silicon or silicon grains smaller than the single silicon grain or the silicon grains in the third silicon region.

4. The method of claim 1, further comprising:
before heating the amorphous silicon layer, forming a second dielectric layer on the amorphous silicon layer.

5. The method of claim 1, further comprising:
forming a second dielectric layer on the first, second and third silicon regions;
removing portions of the second dielectric layer to expose the first silicon region and the second silicon region; and
forming metal contacts, a first metal contact contacting the first silicon region, and a second metal contact contacting the second silicon region.

6. The method of claim 1, wherein the first gap between the first silicide layer and the first dielectric layer is a vacuum gap.

7. The method of claim 1, further comprising:
before forming the first dielectric layer, removing a portion of the first metal layer and the first silicon layer, wherein after treating the first metal layer and the first silicon layer, the first dielectric layer includes a support contacting the surface of the substrate within the gap.

8. The method of claim 1, wherein heating the amorphous silicon layer is performed via excimer laser annealing.

9. The method of claim 1, wherein a thickness of the first gap is about 10 to 50 nanometers.

10. The method of claim 1, further comprising:
forming a second dielectric layer on the third silicon region;
forming a second metal layer on the second dielectric layer;
forming a second silicon layer on the second metal layer;
forming dielectric supports on the second silicon layer and a portion of the second dielectric layer; and
treating the second metal layer and the second silicon layer, wherein the second metal layer reacts with the second silicon layer to form a second silicide layer and a second gap between the second silicide layer and the second dielectric layer.

11. The method of claim 1, further comprising:
implanting an n-type dopant in the first silicon region and the second silicon region.

12. A device fabricated in accordance with the method of claim 1.

13. A method comprising:
providing a substrate having a surface, the substrate including a silicon layer on a region of the surface of the substrate, the silicon layer leaving regions of the substrate surface exposed;
forming a metal layer on the silicon layer;
removing a portion of the metal layer and the silicon layer to expose a portion of the substrate surface;
forming a dielectric layer on the metal layer, the exposed regions of the substrate surface, and the exposed portion of the substrate surface;
treating the metal layer and the silicon layer, wherein the metal layer reacts with the silicon layer to form a silicide layer and a gap between the silicide layer and the dielectric layer;
forming an amorphous silicon layer on the dielectric layer, the amorphous silicon layer including a first silicon region and a second silicon region overlying the exposed regions of the substrate surface and a third silicon region overlying the gap, the third silicon region being between the first silicon region and the second silicon region;
heating the amorphous silicon layer; and
cooling the amorphous silicon layer, wherein the first silicon region and the second silicon region cool at a faster rate than the third silicon region.

14. The method of claim 13, wherein the metal layer includes at least one of titanium, nickel, molybdenum, tantalum, tungsten, platinum and cobalt.

15. The method of claim 13, wherein the third silicon region includes a single silicon grain or silicon grains, and wherein the first and second silicon regions include amorphous silicon or silicon grains smaller than the single silicon grain or the silicon grains in the third silicon region.

16. The method of claim 13, further comprising:
implanting an n-type dopant in the first silicon region and the second silicon region.

17. An apparatus comprising:
a substrate having a surface;
a first silicide layer associated with the substrate surface;
a first dielectric layer, at least a portion of the first dielectric layer on the substrate surface;
a first vacuum gap between the first silicide layer and the first dielectric layer; and
a silicon layer on the first dielectric layer, the silicon layer including a first silicon region, a second silicon region, and a third silicon region, the third silicon region overlying the first vacuum gap, the third silicon region being between the first silicon region and the second silicon region, the third silicon region including a single silicon grain or silicon grains and the first and second silicon regions including amorphous silicon or silicon grains smaller than the single silicon grain or the silicon grains in the third silicon region.

18. The apparatus of claim 17, wherein the first silicide layer is at least one of titanium silicide, nickel silicide, molybdenum silicide, tantalum silicide, tungsten silicide, platinum silicide and cobalt silicide.

19. The apparatus of claim 17, wherein the first vacuum gap is about 10 to 50 nm thick.

20. The apparatus of claim 17, wherein a thickness of the first vacuum gap is configured to increase or decrease due to a change in atmospheric pressure.

21. The apparatus of claim 17, wherein the apparatus is configured to generate an absolute pressure reading.

22. The apparatus of claim 21, wherein the absolute pressure reading is generated by applying a fixed potential to the first silicide layer and determining a current flow between the first and second silicon regions.

23. The apparatus of claim 17, wherein the first silicon region and the second silicon region are implanted with an n-type dopant.

24. The apparatus of claim 17, further comprising:
a second dielectric layer on the third silicon region;
a second silicide layer;
a second vacuum gap between the second dielectric layer and the second silicide layer; and
dielectric supports on a portion of the second dielectric layer, wherein the dielectric supports separate the second silicide layer from the second dielectric layer.

25. The apparatus of claim 17, further comprising:
a display;
a processor that is configured to communicate with the display, the processor being configured to process image data; and
a memory device that is configured to communicate with the processor.

26. The apparatus of claim 25, further comprising:
a driver circuit configured to send at least one signal to the display; and
a controller configured to send at least a portion of the image data to the driver circuit.

27. The apparatus of claim 25, further comprising:
an image source module configured to send the image data to the processor.

28. The apparatus of claim 27, wherein the image source module includes at least one of a receiver, transceiver, and transmitter.

29. The apparatus of claim 25, further comprising:
an input device configured to receive input data and to communicate the input data to the processor.
